(19) United States
(12) Patent Application Publication
(10) Pub. No.: US 2021/0312113 A1
(43) Pub. Date: Oct. 7, 2021

(54) METHOD FOR FINDING EQUIVALENT CLASSES OF HARD DEFECTS IN STACKED MOSFET ARRAYS

(71) Applicant: Synopsys, Inc., Mountain View, CA (US)

(72) Inventors: Mayukh BHATTACHARYA, Palo Alto, CA (US); Michal Jerzy Rewienski, Gdansk (PL); Shan Yuan, San Jose, CA (US); Michael Durr, Livermore, CA (US); Chih Ping Antony Fan, Saratoga, CA (US)

(73) Assignee: Synopsys, Inc., Mountain View, CA (US)

(21) Appl. No.: 17/221,175

(22) Filed: Apr. 2, 2021

Related U.S. Application Data
(60) Provisional application No. 63/004,276, filed on Apr. 2, 2020.

(51) Int. Cl. G06F 30/3323

(52) U.S. Cl. CPC G06F 30/3323

(57) ABSTRACT

In modern VLSI technology, often, stacked arrays of smaller sized MOSFETs are used to achieve the desired width and length of a design MOSFET. In analog defect simulation, each physical transistor can contribute to the circuit's defect universe and this can directly lead to tremendous increase in defect simulation time. Here we propose a method of finding equivalent defects in the context of stacked MOSFET arrays that can lead to significant reduction in defect simulation effort and yet provide accurate defect coverage results.

### CROSS-REFERENCE TO RELATED APPLICATIONS

The present application claims the benefit of U.S. Provisional Patent Application No. 63/004,276, titled “A Method for Finding Equivalent Classes of Hard Defects in Stacked MOSFET Arrays,” filed Apr. 2, 2020, which is hereby incorporated by reference in its entirety for all purposes.

### BACKGROUND

Digital fault simulation, testing, design-for-testability, etc., have matured to such a level that chances of failure in digital component are much lower than in the analog component in modern-day mixed-signal ICs. Properly assessing test coverage for analog circuits necessitates accurate and reasonably fast analog fault simulation capability.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1 illustrates short defects in M*N stacked MOSFET array, according to some embodiments of the present disclosure.

FIG. 2 illustrates open defects in M*N stacked MOSFET array, according to some embodiments of the present disclosure.

FIG. 3 illustrates 6*5 stacked MOSFET array for defect simulation experiments, according to some embodiments of the present disclosure.

FIG. 4 illustrates an input stimuli to the 6×5 stacked MOSFET array of FIG. 3, according to some embodiments of the present disclosure.

FIG. 5 illustrates outputs for Open Drain defects on 30 MOSFETs, according to some embodiments of the present disclosure.

FIG. 6 illustrates outputs for Open Gate defects on 30 MOSFETs, according to some embodiments of the present disclosure.

FIG. 7 illustrates outputs for Open Source defects on 30 MOSFETs, according to some embodiments of the present disclosure.

FIG. 8 illustrates outputs for Short Gate-Drain defects on 30 MOSFETs, according to some embodiments of the present disclosure.

FIG. 9 illustrates outputs for Short Gate-Source defects on 30 MOSFETs, according to some embodiments of the present disclosure.

FIG. 10 illustrates outputs for Short Drain-Source defects on 30 MOSFETs, according to some embodiments of the present disclosure.

FIG. 11 illustrates choosing the class of one defect in a stacked array of identical prelayout MOSFETs, according to some embodiments of the present disclosure.

FIG. 12 illustrates a defect coverage flow, according to some embodiments of the present disclosure.

FIG. 13 depicts a flowchart of various processes used during the design and manufacture of an integrated circuit in accordance with some embodiments of the present disclosure.

FIG. 14 depicts an abstract diagram of an example emulation system in accordance with some embodiments of the present disclosure.

FIG. 15 depicts an abstract diagram of an example computer system in which embodiments of the present disclosure may operate.

### DETAILED DESCRIPTION

Aspects of the present disclosure relate to a method for finding equivalent classes of hard defects in stacked MOSFET arrays.

Digital fault simulation, testing, design-for-testability, etc., have matured to such a level that chances of failure in digital component are much lower than in the analog component in modern-day mixed-signal ICs. In a mixed signal (analog+digital) application, it is now observed that as much as 80% of field returns are attributed to analog portion of the circuits. It is well-known that manufacturing test coverage is directly related to the number of defective chips returned from the field (DL=1−Y^{(1-Tc)}, where DL=Defect Level, Y=Yield, and TC=Test Coverage [Williams and Brown, 1981]). But properly assessing test coverage for analog circuits necessitates accurate and reasonably fast analog fault simulation capability. Also, advanced driver-assist systems (ADAS) are becoming ubiquitous in modern cars and are projected to continue to grow as the automotive industry moves towards totally hands-off-eyes-off autonomous vehicles. Most of the integrated circuits at the heart of the ADAS technologies have significant analog component. Fault simulation of mission-critical circuit components is often suggested as a methodology to compute the quality metrics (e.g., SPFM, LFM, PMHF) recommended by the functional safety standards (e.g., ISO 26262). So, both from manufacturing test coverage and from functional safety standpoints, fast and accurate analog fault/defect simulation is of central importance.

To perform defect simulation for a circuit, the universe of all realistic defects must be enumerated. Unlike digital fault simulation (where concurrent fault simulation is algorithmically possible), usually, in analog circuits, the number of fault simulations is equal to the size of the fault universe if the universe is not analyzed for uniqueness. It is of utmost importance to try and reduce the number of fault simulations (and hence number of unique faults) to be able to keep analog fault simulation practical. Now, if two or more defects can be shown to have the same electrical effect, then they can be considered to belong to the same equivalence class. If a defect is covered or not covered by a test then all other defects belonging to its equivalence class should also be covered or not covered, respectively, by the same test. Hence, fault simulation needs only to be performed for one fault in an equivalence class and the result of such simulation can be shared with the other faults in the class.

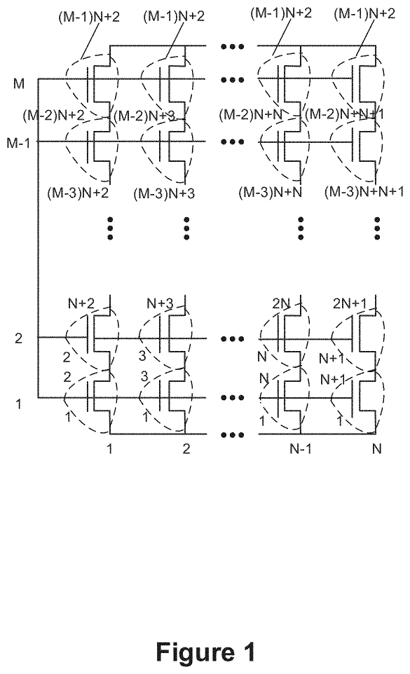

In modern-day CMOS VLSI technology, it is often observed that certain MOSFET technologies (e.g. FinFET) achieve a variety of transistor sizes (width, length) by arranging a number of basic identical transistors in the form of a (stacked) array (not to be confused with the array arrangement of MOSFETs for, say, DRAM MOS cells). FIG. 1 shows the connectivity of M rows and N columns of identical MOSFETs. Electrically, the entire array acts as one single transistor, but physically, M*N transistors exist in the circuit layout. In analog circuits, a variety of transistor sizes across a design are quite common. In some designs, 90% of the transistors are composed of arrays of minimum-sized transistors.

Since short or open defects can occur on each of the physical transistors, the size of the defect universe can be enormous even for a small schematic analog design. For instance, in an industrial OPAMP circuit, effectively, there could be 20 transistors, but to achieve the desired sizes of each transistor, an array of 10 s or 100 s or even 1000 s of smaller physical transistors could be used for each design transistor leading to orders of magnitude increase in defect universe size.

Identifying Stacked MOSFET Arrays

A necessary preliminary step is discovering each stack of MOSFET arrays in a circuit netlist. This can be done from a circuit's netlist representation using a procedure outlined below:
1. Groups of MOSFETs sharing common gate and bulk nodes are discovered, in a manner which is independent of a hierarchical netlist representation of the electrical circuit.
2. Each group is further subdivided to consist of only identical MOSFETs.
3. For each group of identical MOSFETs sharing a common gate and bulk do:
   a. Identify strings of serially connected MOSFETs and replace each string with a single “wrapper” MOSFET. Record the index for the wrapper MOSFET, defined as the number of original MOSFETs in the string. Record the original devices associated with each wrapper.
   b. Group parallel wrapper MOSFETs (i.e. wrapper MOSFETs with identical terminals) with the same index (computed in the previous step). Each group of wrapper-MOSFETs identifies a stacked MOSFET array.
   c. Assign original MOSFETs belonging to the same wrapper MOSFET group a unique “stack index.”

Hard Defects in MOSFET Array

From analog usage perspective, realistic hard defects in MOSFET are of two types: short between two terminals and open at each terminal. Since a typical MOSFET device has four external terminals—Drain, Gate, Source, and Bulk—there can be C₂⁴ or 6 short and 4 open hard defects. If a stacked MOSFET array consists of M rows and N columns of individual MOS devices, then a completely naive enumeration of hard defects would be—M*N*(6+4)=10*M*N. However, since all the MOS devices in the stacked array have their gate terminal connected to the same circuit node, and in each column, the source of one device is connected to the drain of an adjacent device, it is obvious that among the 10*M*N defects, many defects would actually be the same defect multiply counted in the context of different MOSFET transistor's terminals. We refer to such equivalent defects as topologically equivalent defects. For all practical purposes, short or open defects involving the Bulk terminal of a MOSFET are very unlikely and hence, the hard defects associated with one MOSFET usually consist of 3 short and 3 open defects involving the Source, Drain, and Gate terminals only. Our methodology is not restricted to the number of terminals—it is easily applicable to arbitrary number of terminals—but we choose to use the 3-terminal realistic simplification to exemplify the method.

Equivalent Short Defects in Stacked MOSFET Array

FIG. 1 shows an M*N stacked array of MOSFET devices in which the arcs depict the three short defects per transistor. FIG. 1 can illustrate that two short defects are topologically (and hence electrically) completely equivalent if the same set of two terminals are being shorted by each of the defects, and if the resistance value of the short is the same. The numbers next to the short defects are the unique short defect count for the array. Obviously, the total number defects would be 3*M*N. Between two consecutive rows, in each column, the gate-channel (S/D) short defect have the same terminals and hence are topologically equivalent. Since there are M rows, (M−1)*N such defects are double-counted. Also, in the top and bottom rows, the set of short defects between gate and the external node are all parallel, and hence, equivalent. So, 2*N such defects can be represented uniquely by only 2 defects. Hence, we can say that topologically, the number of unique short defects are:

3*M*N−((M−1)*N+2*N−2)=

3*M*N−(M*N+N−2)=

2*M*N−N+2

So far, we have not made any assumption about the nature of the MOSFETs themselves. Now if we assume that the MOSFETs are identical (which is the most common scenario), then further equivalent short defects can perhaps be discovered. For instance, a short across Source-Drain of any of the M MOSFETs in each column would be identical in effect to a short across Source-Drain of the corresponding MOSFET in the same row in another column. This is obvious from the symmetry of the identical MOSFET array connectivity where any two columns could be swapped with one another without making any electrical difference. The above argument could be made for terminal pairs other than Source-Drain as well. Hence, the number of unique short defects would become=2*M+1 (independent of the number of columns).

Going further, one could posit that any short defect on any of the MOSFETs in the array could be electrically equivalent to a similar defect in any other MOSFET belonging to the same array. But this is not correct in general and will be borne out by our experimental results to be presented shortly.

Equivalent Open Defects in Stacked MOSFET Array

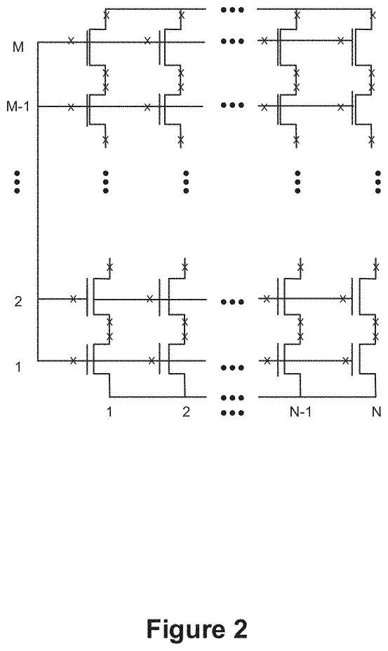

FIG. 2 shows the same M*N stacked array as in FIG. 1. FIG. 2 can illustrate that two open defects are topologically (and hence electrically) completely equivalent if they open the same node. So, open defects of multiple MOSFET terminals which are connected to the same node are equivalent. The little crosses depict the location of possible open defects in the MOSFET terminals. When two such locations are adjacent to one another—for example, on each column the open defect on Source of one transistor and the open defect on the Drain of the immediate neighboring transistor—such defects are topologically (and hence electrically) identical and could be equally represented by either one of the two. Based on this observation, the number of unique open defects are:

3*M*N−N*(M−1)=2*M*N+N

Under the identical MOSFET scenario—as in the case of the short defects—one could argue that an open defect on any MOSFET should be equivalent to a similar open defect on another MOSFET in a different column but on the same row. This means that the number of unique open defects will be independent of the number of columns=2*M+1.

Again, the general claim of equivalence across all MOSFETs can be too strong and will have to be validated by experimental results which we present next.

Simulation Results

From the structure of the M*N MOS array, the effect of a defect in any MOS should be indistinguishable from a similar defect in another MOS in the same row in the array, if the MOSFETs are identical physically and electrically. Intuitively, it also appears that the effect of a defect should be similar across the different rows as well except if they occur on one of the rows as well except if they occur on one of the edge rows—since then the defect may actually directly affect the output port of the MOS array that is associated with that edge row. The purpose of this section is to experimentally validate or refute the above intuitive analysis.

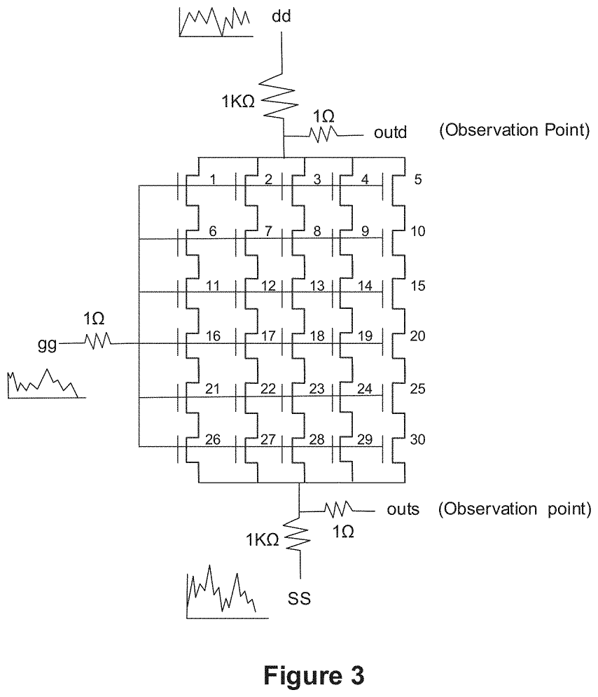

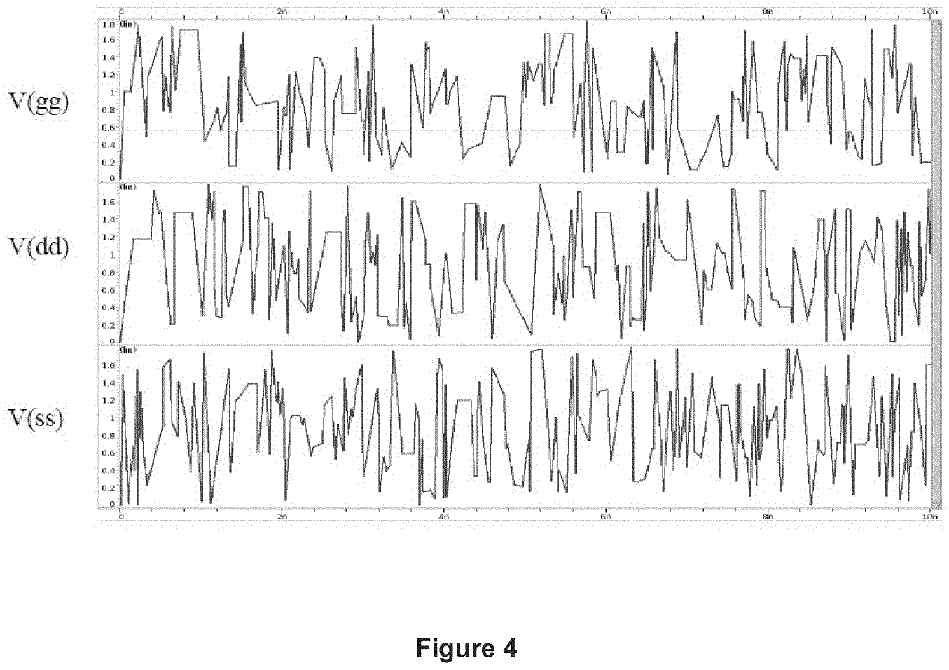

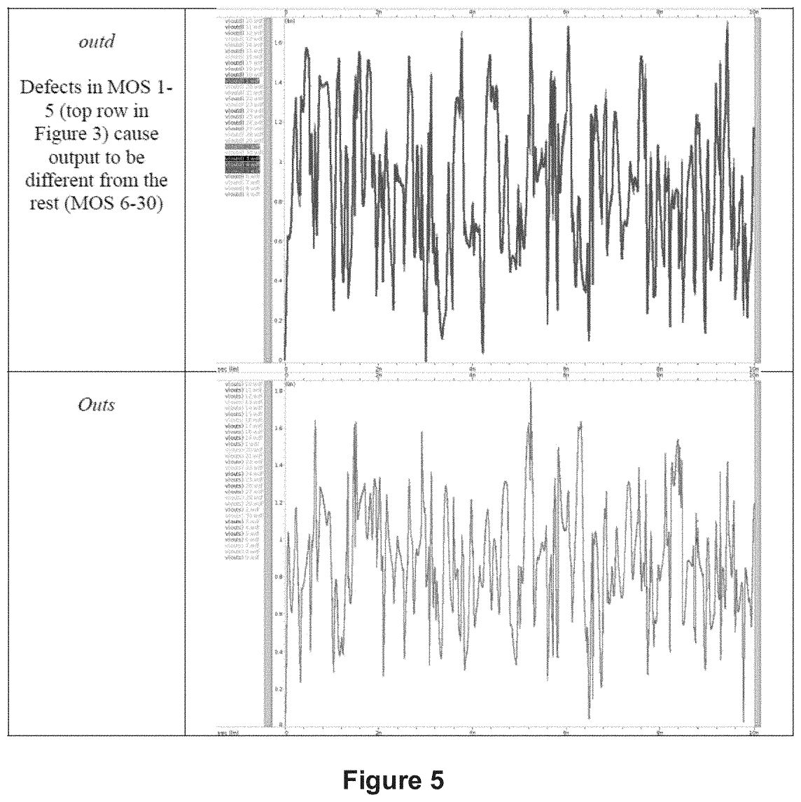

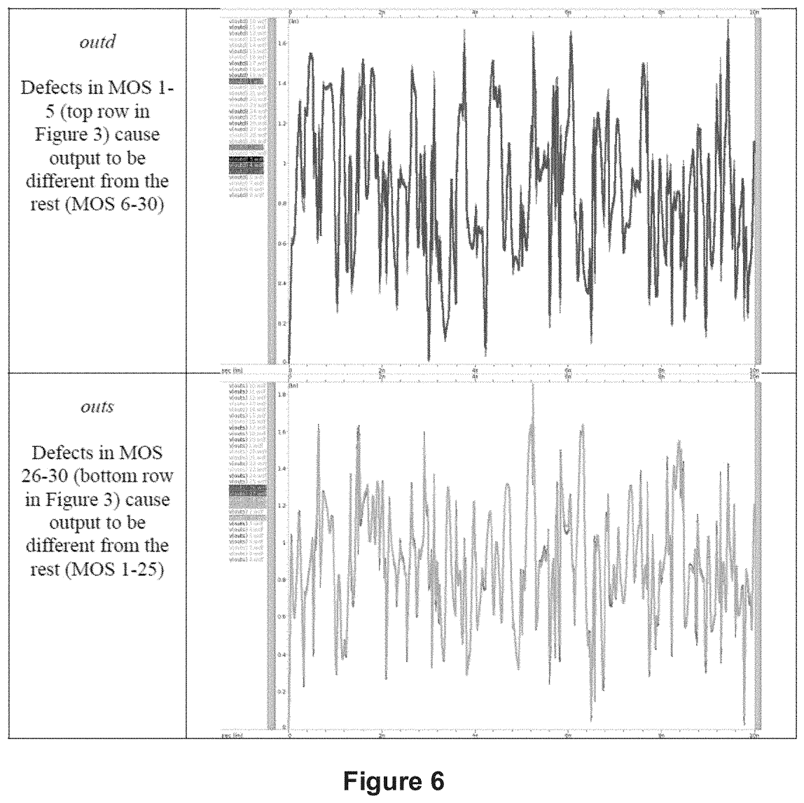

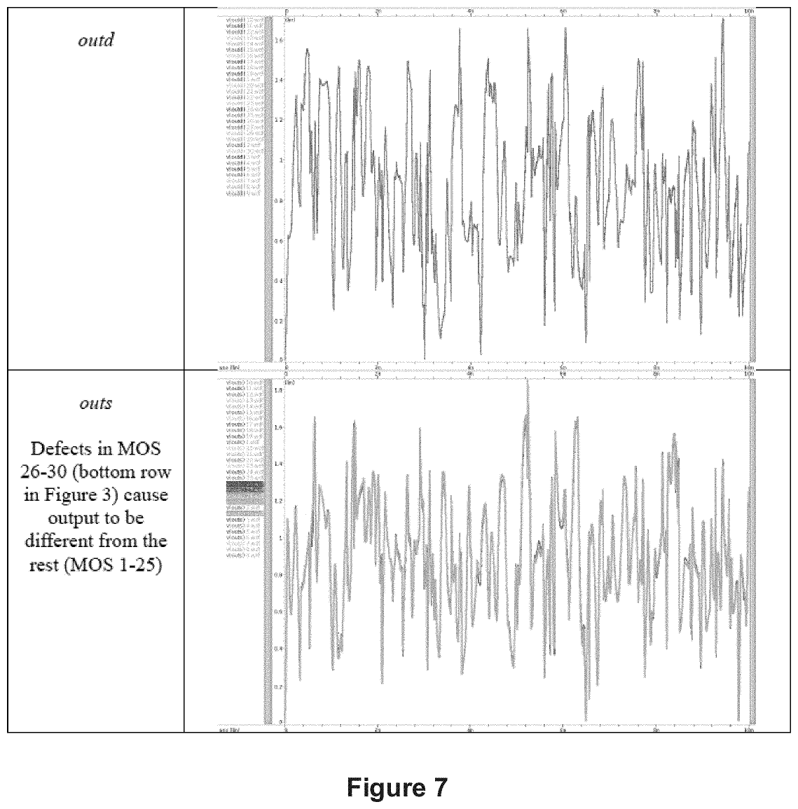

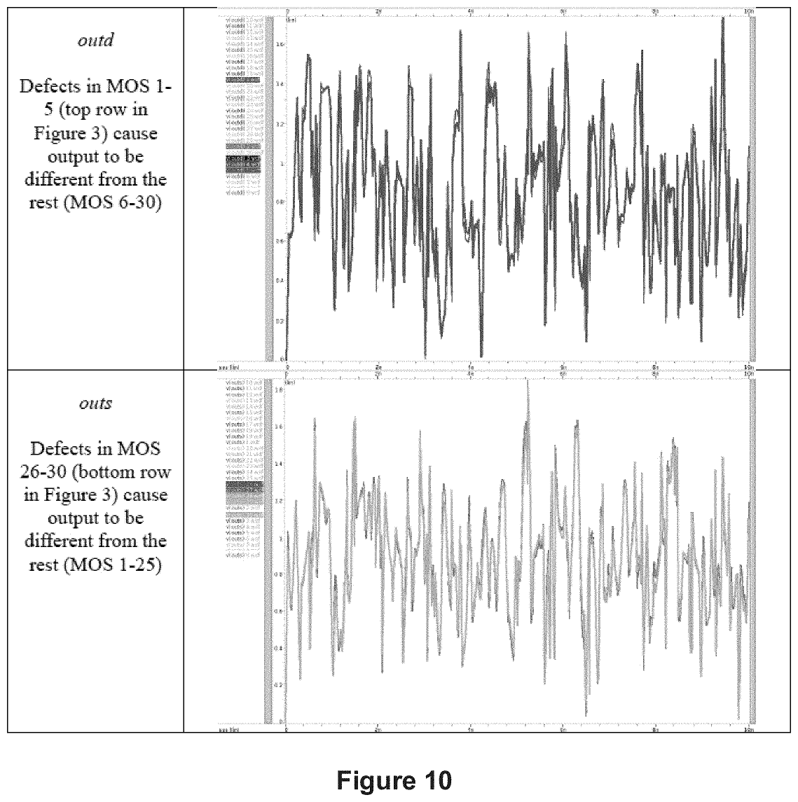

We take a 6*5 NMOS array with generic level=54 MOS models. We construct a circuit as in FIG. 3. FIG. 3 can illustrate that the MOSFETs are numbered 1-30. Pseudo-random PWL signals are applied at the three inputs: “dd”, “gg”, and “ss”. The output behavior is monitored at “outd” and “outs”. The exact nature of the input signals are shown in FIG. 4. The excitations at ports “dd”, “gg”, and “ss” are random PWL (piece-wise-linear) sources that have high and low frequency components to be able to excite various defective behavior in the MOS array—these are shown in FIG. 4. FIG. 4 illustrates input PWL signals. FIGS. 5-10 show the voltages at the observation points “outd” and “outs” for each of the three open and short fault types injected into the 30 MOSFETs.

FIGS. 5-10 validate our assumption that there are three distinct classes of defects in arrays of identical MOSFETs—
1. the defects in MOSFETs in the row touching the external drain (drain-edge MOSFETs),
2. the defects in MOSFETs in the row touching the external source (source-edge MOSFETs), and
3. the defects in the MOSFETs in the internal rows of the array (internal MOSFETs)

Overall Methodology

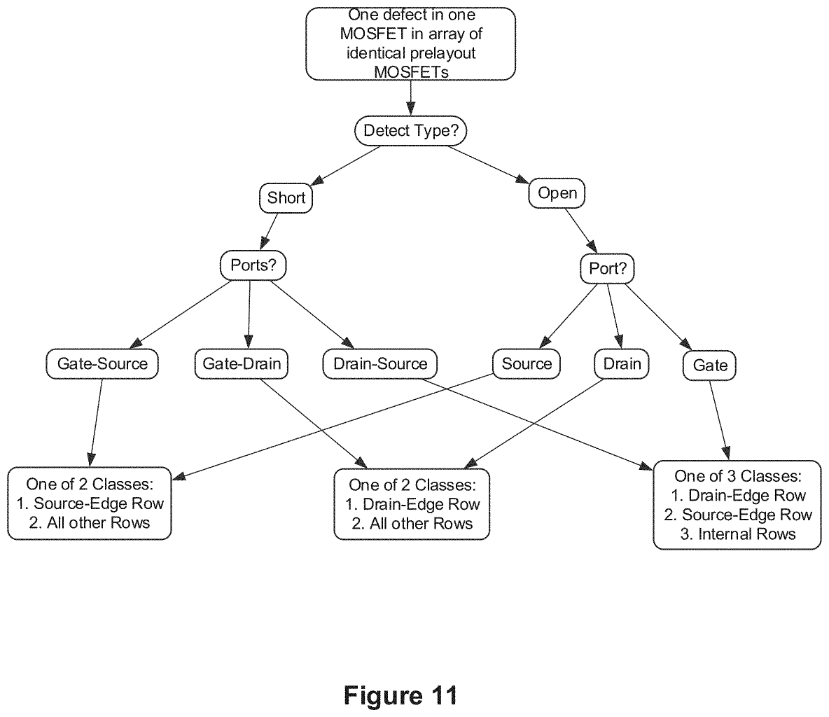

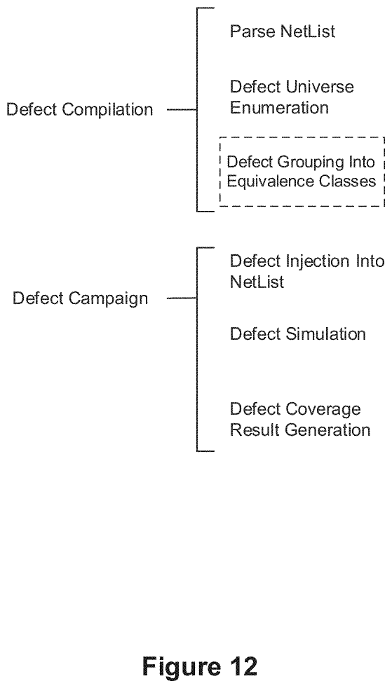

FIG. 11 can illustrate choosing the class of one defect in a stacked array of identical pre-layout MOSFETs. If open and short defects involving the bulk terminal are included, then the flow has to be suitably modified. In some embodiments, FIG. 11 can illustrate equivalence classification. The overall flow of defect coverage calculation can be summarized by FIG. 12. FIG. 12 can illustrate the salient steps necessary for defect coverage calculation. The defect equivalent class grouping step is where the present methodology can be effective in netlists that have stacked arrays of MOSFETs. The present methodology is applicable in the phase marked by the dashed box. Based on the above analysis, our methodology for classifying defects in a stacked MOSFET array is as follows:
1. Identification of stacked MOSFET arrays.
2. Topological equivalence: Based on FIGS. 1 and 2, short and defects are classified into equivalence classes. One defect from each class is picked and then further classified by step 2.
3. Electrical equivalence: From each class above, one defect is picked and then it is further classified by the logic of FIG. 11.

For defect simulation, only one defect per equivalence class needs to be simulated and the result of such simulation should be shared among all defects in a class.

### CONCLUSIONS

We have presented a methodology of identifying equivalent classes of hard/catastrophic/gross defects (shorts and opens) that may occur in MOSFETs in a stacked MOSFET array of identical MOSFETs in a schematic netlist. The method can be used even if the MOSFETs are not completely identical and there are postlayout elements within the array structure of the MOSFETs if the devices are not too different from one another and the parasitic resistors and capacitors are reasonably small in value compared to the MOSFET impedance and capacitance.

Our method involves:
1. finding the stacked arrays of MOSFETs in a circuit netlist (e.g., in SPICE, SPECTRE, ELDO, etc. formats),
2. grouping the various short and open defects based on topology and electrical properties
3. injecting one defect per equivalence class and doing a defect simulation
4. attributing the simulation result to the rest of the defects in the same class

By means of the above approach, the total number of simulations can be reduced from O(M*N) to O(1)—which is a significant saving in simulation effort. The defect coverage calculation based on this method should be the same as what can be achieved by exhaustive defect simulation, but with much less number of defect simulations.

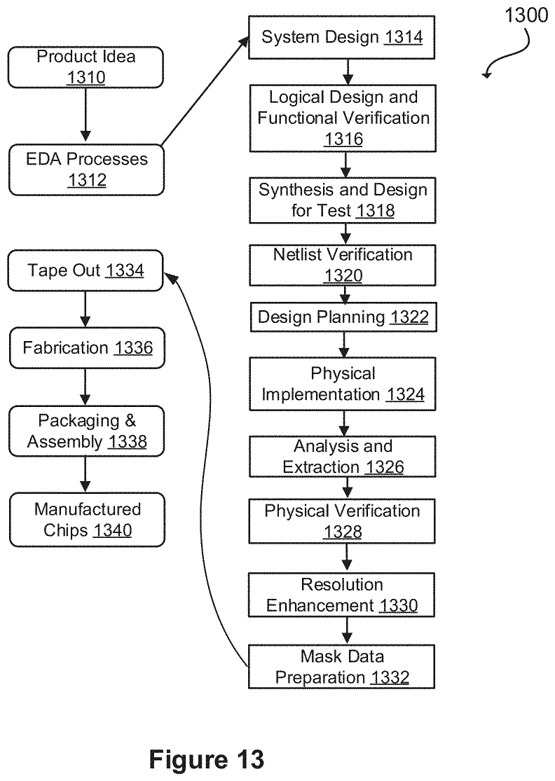

FIG. 13 illustrates an example set of processes 700 used during the design, verification, and fabrication of an article of manufacture such as an integrated circuit to transform and verify design data and instructions that represent the integrated circuit. Each of these processes can be structured and enabled as multiple modules or operations. The term ‘EDA’ signifies the term ‘Electronic Design Automation.’ These processes start with the creation of a product idea 1310 with information supplied by a designer, information which is transformed to create an article of manufacture that uses a set of EDA processes 1312. When the design is finalized, the design is taped-out 1334, which is when artwork (e.g., geometric patterns) for the integrated circuit is sent to a fabrication facility to manufacture the mask set, which is then used to manufacture the integrated circuit. After tape-out, a semiconductor die is fabricated 1336 and packaging and assembly processes 1338 are performed to produce the finished integrated circuit 1340.

Specifications for a circuit or electronic structure may range from low-level transistor material layouts to high-level description languages. A high-level of abstraction may be used to design circuits and systems, using a hardware description language (‘HDL’) such as VHDL, Verilog, SystemVerilog, SystemC, MyHDL or OpenVera. The HDL description can be transformed to a logic-level register transfer level (‘RTL’) description, a gate-level description, a layout-level description, or a mask-level description. Each lower abstraction level that is a less abstract description adds more useful detail into the design description, for example, more details for the modules that include the description. The lower levels of abstraction that are less abstract descriptions can be generated by a computer, derived from a design library, or created by another design automation process. An example of a specification language at a lower level of abstraction language for specifying more detailed descriptions is SPICE, which is used for detailed descriptions of circuits with many analog components. Descriptions at each level of abstraction are enabled for use by the corresponding tools of that layer (e.g., a formal verification tool). A design process may use a sequence depicted in FIG. 13. The processes described by be enabled by EDA products (or tools).

During system design 1314, functionality of an integrated circuit to be manufactured is specified. The design may be optimized for desired characteristics such as power consumption, performance, area (physical and/or lines of code), and reduction of costs, etc. Partitioning of the design into different types of modules or components can occur at this stage.

During logic design and functional verification 1316, modules or components in the circuit are specified in one or more description languages and the specification is checked for functional accuracy. For example, the components of the circuit may be verified to generate outputs that match the requirements of the specification of the circuit or system being designed. Functional verification may use simulators and other programs such as testbench generators, static HDL checkers, and formal verifiers. In some embodiments, special systems of components referred to as ‘emulators’ or ‘prototyping systems’ are used to speed up the functional verification.

During synthesis and design for test 1318, HDL code is transformed to a netlist. In some embodiments, a netlist may be a graph structure where edges of the graph structure represent components of a circuit and where the nodes of the graph structure represent how the components are interconnected. Both the HDL code and the netlist are hierarchical articles of manufacture that can be used by an EDA product to verify that the integrated circuit, when manufactured, performs according to the specified design. The netlist can be optimized for a target semiconductor manufacturing technology. Additionally, the finished integrated circuit may be tested to verify that the integrated circuit satisfies the requirements of the specification.

During netlist verification 1320, the netlist is checked for compliance with timing constraints and for correspondence with the HDL code. During design planning 1322, an overall floor plan for the integrated circuit is constructed and analyzed for timing and top-level routing.

During layout or physical implementation 1324, physical placement (positioning of circuit components such as transistors or capacitors) and routing (connection of the circuit components by multiple conductors) occurs, and the selection of cells from a library to enable specific logic functions can be performed. As used herein, the term ‘cell’ may specify a set of transistors, other components, and interconnections that provides a Boolean logic function (e.g., AND, OR, NOT, XOR) or a storage function (such as a flipflop or latch). As used herein, a circuit ‘block’ may refer to two or more cells. Both a cell and a circuit block can be referred to as a module or component and are enabled as both physical structures and in simulations. Parameters are specified for selected cells (based on ‘standard cells’) such as size and made accessible in a database for use by EDA products.

During analysis and extraction 1326, the circuit function is verified at the layout level, which permits refinement of the layout design. During physical verification 1328, the layout design is checked to ensure that manufacturing constraints are correct, such as DRC constraints, electrical constraints, lithographic constraints, and that circuitry function matches the HDL design specification. During resolution enhancement 1330, the geometry of the layout is transformed to improve how the circuit design is manufactured.

During tape-out, data is created to be used (after lithographic enhancements are applied if appropriate) for production of lithography masks. During mask data preparation 1332, the ‘tape-out’ data is used to produce lithography masks that are used to produce finished integrated circuits.

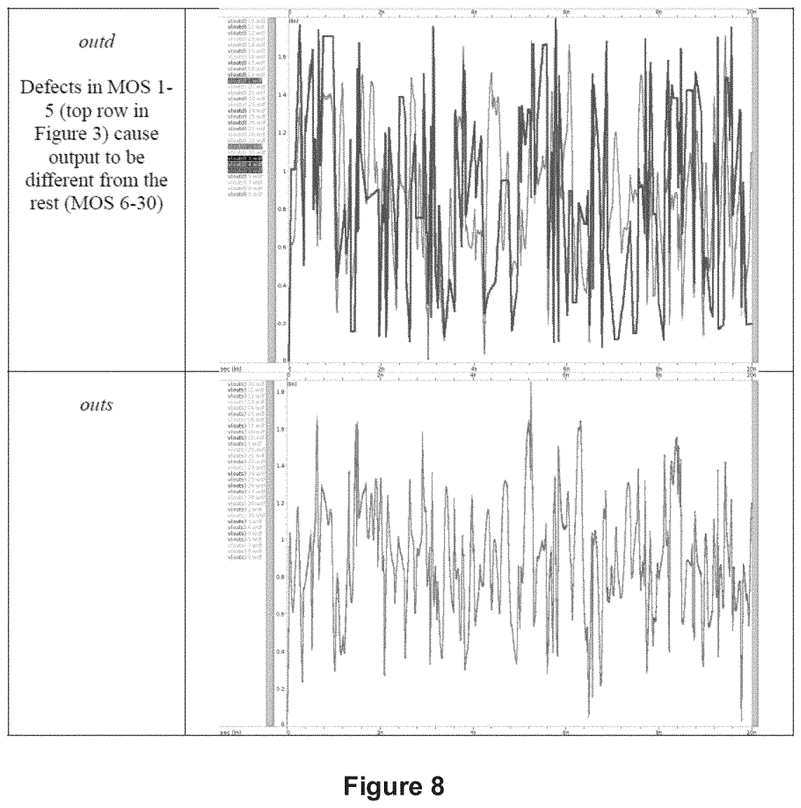

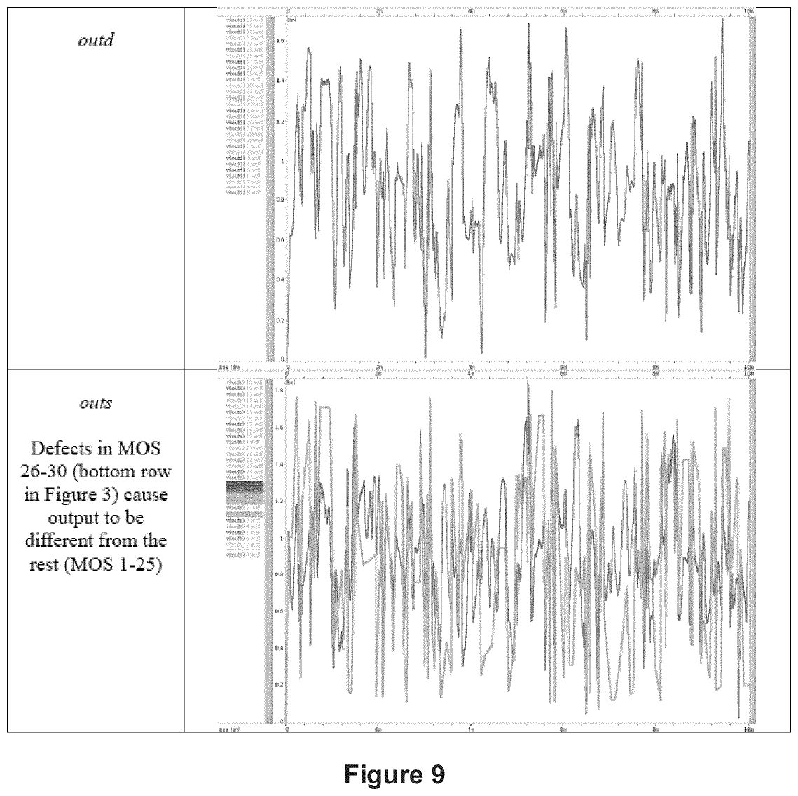

A storage subsystem of a computer system (such as computer system 1500 of FIG. 9, or host system 1407 of FIG. 8) may be used to store the programs and data structures that are used by some or all of the EDA products described herein, and products used for development of cells for the library and for physical and logical design that use the library.

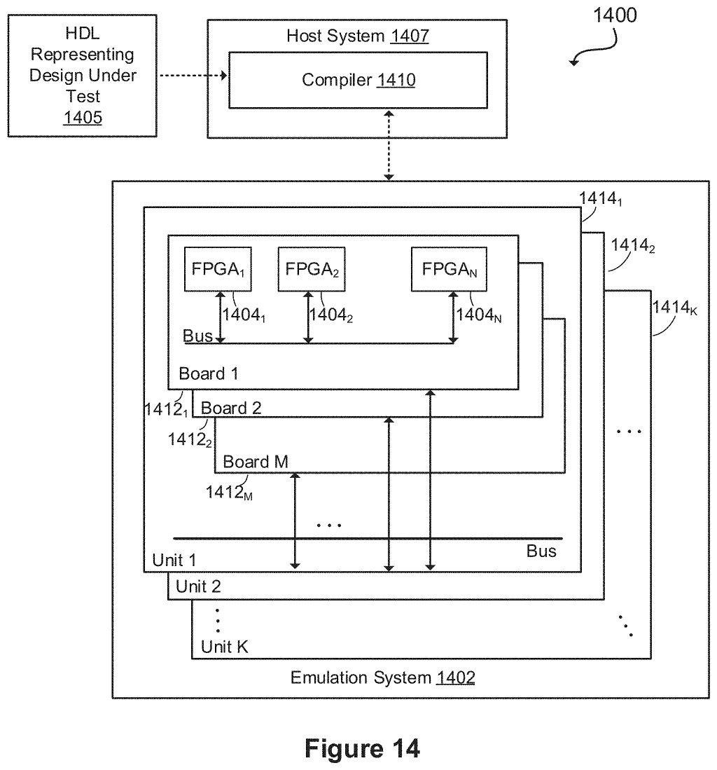

FIG. 14 depicts an abstract diagram of an example emulation environment 1400. An emulation environment 1400 may be configured to verify the functionality of the circuit design. The emulation environment 1400 may include a host system 1407 (e.g., a computer that is part of an EDA system) and an emulation system 1402 (e.g., a set of programmable devices such as Field Programmable Gate Arrays (FPGAs) or processors). The host system generates data and information by using a compiler 1410 to structure the emulation system to emulate a circuit design. A circuit design to be emulated is also referred to as a Design Under Test (‘DUT’) where data and information from the emulation are used to verify the functionality of the DUT.

The host system 1407 may include one or more processors. In the embodiment where the host system includes multiple processors, the functions described herein as being performed by the host system can be distributed among the multiple processors. The host system 1407 may include a compiler 1410 to transform specifications written in a description language that represents a DUT and to produce data (e.g., binary data) and information that is used to structure the emulation system 1402 to emulate the DUT. The compiler 1410 can transform, change, restructure, add new functions to, and/or control the timing of the DUT.

The host system 1407 and emulation system 1402 exchange data and information using signals carried by an emulation connection. The connection can be, but is not limited to, one or more electrical cables such as cables with pin structures compatible with the Recommended Standard 232 (RS232) or universal serial bus (USB) protocols. The connection can be a wired communication medium or network such as a local area network or a wide area network such as the Internet. The connection can be a wireless communication medium or a network with one or more points of access using a wireless protocol such as BLUETOOTH or IEEE 1402.11. The host system 1407 and emulation system 1402 can exchange data and information through a third device such as a network server.

The emulation system 1402 includes multiple FPGAs (or other modules) such as FPGAs 1404₁ and 1404₂ as well as additional FPGAs to 1404_{N}. Each FPGA can include one or more FPGA interfaces through which the FPGA is connected to other FPGAs (and potentially other emulation components) for the FPGAs to exchange signals. An FPGA interface can be referred to as an input/output pin or an FPGA pad. While an emulator may include FPGAs, embodiments of emulators can include other types of logic blocks instead of, or along with, the FPGAs for emulating DUTs. For example, the emulation system 1402 can include custom FPGAs, specialized ASICs for emulation or prototyping, memories, and input/output devices.

A programmable device can include an array of programmable logic blocks and a hierarchy of interconnections that can enable the programmable logic blocks to be interconnected according to the descriptions in the HDL code. Each of the programmable logic blocks can enable complex combinational functions or enable logic gates such as AND, and XOR logic blocks. In some embodiments, the logic blocks also can include memory elements/devices, which can be simple latches, flip-flops, or other blocks of memory. Depending on the length of the interconnections between different logic blocks, signals can arrive at input terminals of the logic blocks at different times and thus may be temporarily stored in the memory elements/devices.

FPGAs 1404₁-1404_{N} may be placed onto one or more boards 1412₁ and 1412₂ as well as additional boards through 1412_{M}. Multiple boards can be placed into an emulation unit 1414₁. The boards within an emulation unit can be connected using the backplane of the emulation unit or any other types of connections. In addition, multiple emulation units (e.g., 1414₁ and 1414₂ through 1414_{K}) can be connected to each other by cables or any other means to form a multi-emulation unit system.

For a DUT that is to be emulated, the host system 300 transmits one or more bit files to the emulation system 1402. The bit files may specify a description of the DUT and may further specify partitions of the DUT created by the host system 1407 with trace and injection logic, mappings of the partitions to the FPGAs of the emulator, and design constraints. Using the bit files, the emulator structures the FPGAs to perform the functions of the DUT. In some embodiments, one or more FPGAs of the emulators may have the trace and injection logic built into the silicon of the FPGA. In such an embodiment, the FPGAs may not be structured by the host system to emulate trace and injection logic.

The host system 1407 receives a description of a DUT that is to be emulated. In some embodiments, the DUT description is in a description language (e.g., a register transfer language (RTL)). In some embodiments, the DUT description is in netlist level files or a mix of netlist level files and HDL files. If part of the DUT description or the entire DUT description is in an HDL, then the host system can synthesize the DUT description to create a gate level netlist using the DUT description. A host system can use the netlist of the DUT to partition the DUT into multiple partitions where one or more of the partitions include trace and injection logic. The trace and injection logic traces interface signals that are exchanged via the interfaces of an FPGA. Additionally, the trace and injection logic can inject traced interface signals into the logic of the FPGA. The host system maps each partition to an FPGA of the emulator. In some embodiments, the trace and injection logic is included in select partitions for a group of FPGAs. The trace and injection logic can be built into one or more of the FPGAs of an emulator. The host system can synthesize multiplexers to be mapped into the FPGAs. The multiplexers can be used by the trace and injection logic to inject interface signals into the DUT logic.

The host system creates bit files describing each partition of the DUT and the mapping of the partitions to the FPGAs. For partitions in which trace and injection logic are included, the bit files also describe the logic that is included. The bit files can include place and route information and design constraints. The host system stores the bit files and information describing which FPGAs are to emulate each component of the DUT (e.g., to which FPGAs each component is mapped).

Upon request, the host system transmits the bit files to the emulator. The host system signals the emulator to start the emulation of the DUT. During emulation of the DUT or at the end of the emulation, the host system receives emulation results from the emulator through the emulation connection. Emulation results are data and information generated by the emulator during the emulation of the DUT which include interface signals and states of interface signals that have been traced by the trace and injection logic of each FPGA. The host system can store the emulation results and/or transmits the emulation results to another processing system.

After emulation of the DUT, a circuit designer can request to debug a component of the DUT. If such a request is made, the circuit designer can specify a time period of the emulation to debug. The host system identifies which FPGAs are emulating the component using the stored information. The host system retrieves stored interface signals associated with the time period and traced by the trace and injection logic of each identified FPGA. The host system signals the emulator to re-emulate the identified FPGAs. The host system transmits the retrieved interface signals to the emulator to re-emulate the component for the specified time period. The trace and injection logic of each identified FPGA injects its respective interface signals received from the host system into the logic of the DUT mapped to the FPGA. In case of multiple re-emulations of an FPGA, merging the results produces a full debug view.

The host system receives, from the emulation system, signals traced by logic of the identified FPGAs during the re-emulation of the component. The host system stores the signals received from the emulator. The signals traced during the re-emulation can have a higher sampling rate than the sampling rate during the initial emulation. For example, in the initial emulation a traced signal can include a saved state of the component every X milliseconds. However, in the re-emulation the traced signal can include a saved state every Y milliseconds where Y is less than X. If the circuit designer requests to view a waveform of a signal traced during the re-emulation, the host system can retrieve the stored signal and display a plot of the signal. For example, the host system can generate a waveform of the signal. Afterwards, the circuit designer can request to re-emulate the same component for a different time period or to re-emulate another component.

A host system 1407 and/or the compiler 1410 may include sub-systems such as, but not limited to, a design synthesizer sub-system, a mapping sub-system, a run time sub-system, a results sub-system, a debug sub-system, a waveform sub-system, and a storage sub-system. The sub-systems can be structured and enabled as individual or multiple modules or two or more may be structured as a module. Together these sub-systems structure the emulator and monitor the emulation results.

The design synthesizer sub-system transforms the HDL that is representing a DUT 1405 into gate level logic. For a DUT that is to be emulated, the design synthesizer sub-system receives a description of the DUT. If the description of the DUT is fully or partially in HDL (e.g., RTL or other level of abstraction), the design synthesizer sub-system synthesizes the HDL of the DUT to create a gate-level netlist with a description of the DUT in terms of gate level logic.

The mapping sub-system partitions DUTs and maps the partitions into emulator FPGAs. The mapping sub-system partitions a DUT at the gate level into a number of partitions using the netlist of the DUT. For each partition, the mapping sub-system retrieves a gate level description of the trace and injection logic and adds the logic to the partition. As described above, the trace and injection logic included in a partition is used to trace signals exchanged via the interfaces of an FPGA to which the partition is mapped (trace interface signals). The trace and injection logic can be added to the DUT prior to the partitioning. For example, the trace and injection logic can be added by the design synthesizer sub-system prior to or after the synthesizing the HDL of the DUT.

In addition to including the trace and injection logic, the mapping sub-system can include additional tracing logic in a partition to trace the states of certain DUT components that are not traced by the trace and injection. The mapping sub-system can include the additional tracing logic in the DUT prior to the partitioning or in partitions after the partitioning. The design synthesizer sub-system can include the additional tracing logic in an HDL description of the DUT prior to synthesizing the HDL description.

The mapping sub-system maps each partition of the DUT to an FPGA of the emulator. For partitioning and mapping, the mapping sub-system uses design rules, design constraints (e.g., timing or logic constraints), and information about the emulator. For components of the DUT, the mapping sub-system stores information in the storage sub-system describing which FPGAs are to emulate each component.

Using the partitioning and the mapping, the mapping sub-system generates one or more bit files that describe the created partitions and the mapping of logic to each FPGA of the emulator. The bit files can include additional information such as constraints of the DUT and routing information of connections between FPGAs and connections within each FPGA. The mapping sub-system can generate a bit file for each partition of the DUT and can store the bit file in the storage sub-system. Upon request from a circuit designer, the mapping sub-system transmits the bit files to the emulator, and the emulator can use the bit files to structure the FPGAs to emulate the DUT.

If the emulator includes specialized ASICs that include the trace and injection logic, the mapping sub-system can generate a specific structure that connects the specialized ASICs to the DUT. In some embodiments, the mapping sub-system can save the information of the traced/injected signal and where the information is stored on the specialized ASIC.

The run time sub-system controls emulations performed by the emulator. The run time sub-system can cause the emulator to start or stop executing an emulation. Additionally, the run time sub-system can provide input signals and data to the emulator. The input signals can be provided directly to the emulator through the connection or indirectly through other input signal devices. For example, the host system can control an input signal device to provide the input signals to the emulator. The input signal device can be, for example, a test board (directly or through cables), signal generator, another emulator, or another host system.

The results sub-system processes emulation results generated by the emulator. During emulation and/or after completing the emulation, the results sub-system receives emulation results from the emulator generated during the emulation. The emulation results include signals traced during the emulation. Specifically, the emulation results include interface signals traced by the trace and injection logic emulated by each FPGA and can include signals traced by additional logic included in the DUT. Each traced signal can span multiple cycles of the emulation. A traced signal includes multiple states and each state is associated with a time of the emulation. The results sub-system stores the traced signals in the storage sub-system. For each stored signal, the results sub-system can store information indicating which FPGA generated the traced signal.

The debug sub-system allows circuit designers to debug DUT components. After the emulator has emulated a DUT and the results sub-system has received the interface signals traced by the trace and injection logic during the emulation, a circuit designer can request to debug a component of the DUT by re-emulating the component for a specific time period. In a request to debug a component, the circuit designer identifies the component and indicates a time period of the emulation to debug. The circuit designer's request can include a sampling rate that indicates how often states of debugged components should be saved by logic that traces signals.

The debug sub-system identifies one or more FPGAs of the emulator that are emulating the component using the information stored by the mapping sub-system in the storage sub-system. For each identified FPGA, the debug sub-system retrieves, from the storage sub-system, interface signals traced by the trace and injection logic of the FPGA during the time period indicated by the circuit designer. For example, the debug sub-system retrieves states traced by the trace and injection logic that are associated with the time period.

The debug sub-system transmits the retrieved interface signals to the emulator. The debug sub-system instructs the debug sub-system to use the identified FPGAs and for the trace and injection logic of each identified FPGA to inject its respective traced signals into logic of the FPGA to re-emulate the component for the requested time period. The debug sub-system can further transmit the sampling rate provided by the circuit designer to the emulator so that the tracing logic traces states at the proper intervals.

To debug the component, the emulator can use the FPGAs to which the component has been mapped. Additionally, the re-emulation of the component can be performed at any point specified by the circuit designer.

For an identified FPGA, the debug sub-system can transmit instructions to the emulator to load multiple emulator FPGAs with the same configuration of the identified FPGA. The debug sub-system additionally signals the emulator to use the multiple FPGAs in parallel. Each FPGA from the multiple FPGAs is used with a different time window of the interface signals to generate a larger time window in a shorter amount of time. For example, the identified FPGA can require an hour or more to use a certain amount of cycles. However, if multiple FPGAs have the same data and structure of the identified FPGA and each of these FPGAs runs a subset of the cycles, the emulator can require a few minutes for the FPGAs to collectively use all the cycles.

A circuit designer can identify a hierarchy or a list of DUT signals to re-emulate. To enable this, the debug sub-system determines the FPGA needed to emulate the hierarchy or list of signals, retrieves the necessary interface signals, and transmits the retrieved interface signals to the emulator for re-emulation. Thus, a circuit designer can identify any element (e.g., component, device, or signal) of the DUT to debug/re-emulate.

The waveform sub-system generates waveforms using the traced signals. If a circuit designer requests to view a waveform of a signal traced during an emulation run, the host system retrieves the signal from the storage sub-system. The waveform sub-system displays a plot of the signal. For one or more signals, when the signals are received from the emulator, the waveform sub-system can automatically generate the plots of the signals.

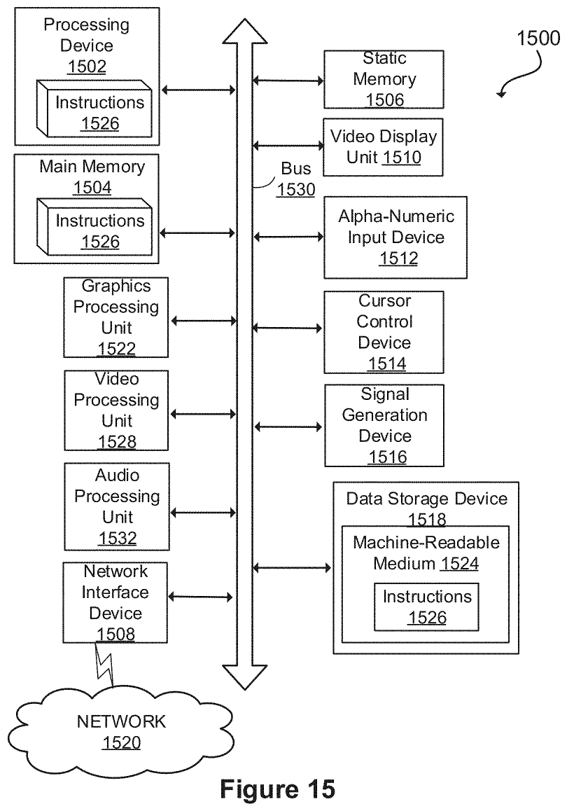

FIG. 15 illustrates an example machine of a computer system 1500 within which a set of instructions, for causing the machine to perform any one or more of the methodologies discussed herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 1500 includes a processing device 1502, a main memory 1504 (e.g., read-only memory (ROM), flash memory, dynamic random access memory (DRAM) such as synchronous DRAM (SDRAM), a static memory 1506 (e.g., flash memory, static random access memory (SRAM), etc.), and a data storage device 1518, which communicate with each other via a bus 1530.

Processing device 1502 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 1502 may also be one or more special-purpose processing devices such as an application specific integrated circuit (ASIC), a field programmable gate array (FPGA), a digital signal processor (DSP), network processor, or the like. The processing device 1502 may be configured to execute instructions 1526 for performing the operations and steps described herein.

The computer system 1500 may further include a network interface device 1508 to communicate over the network 1520. The computer system 1500 also may include a video display unit 1510 (e.g., a liquid crystal display (LCD) or a cathode ray tube (CRT)), an alphanumeric input device 1512 (e.g., a keyboard), a cursor control device 1514 (e.g., a mouse), a graphics processing unit 1522, a signal generation device 1516 (e.g., a speaker), graphics processing unit 1522, video processing unit 1528, and audio processing unit 1532.

The data storage device 1518 may include a machine-readable storage medium 1524 (also known as a non-transitory computer-readable medium) on which is stored one or more sets of instructions 1526 or software embodying any one or more of the methodologies or functions described herein. The instructions 1526 may also reside, completely or at least partially, within the main memory 1504 and/or within the processing device 1502 during execution thereof by the computer system 1500, the main memory 1504 and the processing device 1502 also constituting machine-readable storage media.

In some implementations, the instructions 1526 include instructions to implement functionality corresponding to the present disclosure. While the machine-readable storage medium 1524 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 1502 to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. A method, comprising:
identifying a stacked MOSFET array, wherein the MOSFET array comprises a plurality of MOSFETs sharing common gate and bulk nodes, and wherein the plurality of MOSFETs comprises a first number of short defects and a second number of open defects;
grouping the first number of short defects and the second number of open defects into at least one equivalence class based at least in part on a topological equivalence and an electrical equivalence of the first number of short defects and the second number of open defects;
performing a defect simulation on a simulation defect in the at least one equivalence class; and
attributing the defect simulation of the simulation defect in the at least one equivalence class to at least one other defect in the at least one equivalence class.
